(19) United States
(12) Patent Application Publication
(10) Pub. No.: US 2007/0082225 A1
(43) Pub. Date: Apr. 12, 2007

(54) Method for preserving organic polymeric material and organic electroluminescent device

(75) Inventors: Takashi Shinohara, Nagano-ken (JP); Yuji Shinohara, Nagano-ken (JP); Koichi Terao, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/574,539

(22) PCT Filed: Sep. 24, 2004
(86) PCT No.: PCT/JP04/14458

§ 371 Date: Apr. 3, 2006

(30) Foreign Application Priority Data
Oct. 1, 2003 (JP) 2003-343703

(51) Int. Cl. B32B 19/00

(52) U.S. Cl. 428/690

(57) ABSTRACT

A method for preserving an organic polymeric material, wherein an organic polymeric material which exhibits strong acidity is preserved with it being dissolved or dispersed in a liquid mainly comprised of water, the method is characterized in that the organic polymeric material is preserved with it being dissolved or dispersed in the liquid so that a concentration thereof is 2 wt %, and a pH (at 25° C.) of the thus obtained liquid is measured and then adjusted so as to be to be higher than the measured pH (at 25° C.). Further, it is preferred that a pH (25° C.) of the liquid before the pH adjustment is 2.2 or lower and a pH (25° C.) of the liquid after the pH adjustment is in the range of 2.5 to 7.5. According to this, even if the organic polymeric material is preserved for a long period of time, it is possible to prevent or reduce a change in a molecular structure thereof with the lapse of time.

### TECHNICAL FIELD

The present invention relates to a method for preserving an organic polymeric material and an organic electroluminescent device.

### BACKGROUND ART

There is known an organic electroluminescent device (hereinafter, referred to as an “organic EL device”). The organic EL device has a structure in which at least one light emitting organic layer (organic electroluminescent layer) is provided between a cathode and an anode. Such an organic EL device can significantly reduce a voltage to be applied as compared with an inorganic EL device. Further, it is also possible to manufacture devices that can provide various luminescent colors.

Currently, in order to obtain higher-performance organic EL devices, various researches are being actively carried out, through which many technical ideas have been proposed in developments and improvements of materials to be used as well as device structures thereof.

Up to now, organic EL devices that can provide various luminescent colors or organic EL devices that have high luminance and high efficiency have been already developed, and in order to realize their various practical uses such as application to a picture element of a display or a light source, further researches are being carried out.

In the meantime, as a method for forming organic layers constituting the organic EL device as described above, a wet method is generally employed. In the wet method, each of the organic layers is formed by dissolving or dispersing a functional organic material in an organic solvent to prepare a coating material and then applying the coating material by a spin coating method or the like. Unlike vacuum thin film technology such as a vacuum evaporation method or the like, such a wet method does not require large-scale equipment such as vacuum equipment. Therefore, the use of the wet method makes it possible to simplify the process of manufacturing organic EL devices and reduce the manufacturing cost thereof.

However, a problem exists with such a wet method in that it is difficult to form organic layers into a laminated structure. For example, there is a problem that when a coating material containing an organic solvent for forming a second organic layer is applied onto a first organic layer constituted of an organic material, the organic material constituting the first layer is dissolved by the organic solvent contained in the coating material for the second organic layer, so that the interface between the first organic layer and the second organic layer becomes unclear.

In order to solve such a problem, a method using water to prepare a coating material for use in forming a second organic layer (hereinafter, referred to as a “coating material for forming a second layer”) has been proposed. Many organic materials are hard to dissolve in water. Therefore, by using a coating material for forming a second layer prepared with water, it is possible to form a second organic layer on a first organic layer without dissolving an organic material constituting the first organic layer. In this method, the coating material for forming a second layer is prepared as a dispersion liquid obtained by dispersing an organic material in water because, as described above, organic materials are hard to dissolve in water. However, in such a case, there is also a problem that organic materials generally have low dispersibility in water.

In order to solve such a problem, a structure capable of improving the dispersibility of an organic material is added to a basic structure of the organic material. For example, in the case where polyethylene-di-oxythiophene is used as a hole transport material, polystyrenesulfonic acid is introduced thereinto as a structure for improving the dispersibility of polyethylene-di-oxythiophene (see Japanese Patent Laid-open No. 2001-261795, for example).

In such a polyethylene-di-oxythiophene into which polystyrenesulfonic acid has been introduced, in order to improve a hole transport ability thereof due to a doping effect obtained by the introduction of polystyrenesulfonic acid and improve dispersibility thereof in water, it is in a dispersion state in water from a synthesis step thereof, and is preserved for a long period of time with it being dispersed in water.

However, another problem exists with such a method in that the polyethylene-di-oxythiophene, into which polystyrenesulfonic acid has been introduced, exhibits strong acidity in a state where it is dispersed in water due to a sulfone group contained in polystyrenesulfonic acid, causing a change in the structure thereof with the lapse of time during long-term preservation.

As a result, when an organic EL device is formed using such polyethylene-di-oxythiophene into which polystyrenesulfonic acid has been introduced and which has been preserved for a long period of time in a dispersion state in water, it is not possible to obtain satisfactory light-emission luminance.

### DISCLOSURE OF INVENTION

It is therefore an object of the present invention to provide a method for preserving an organic polymeric material, by which an organic polymeric material that exhibits strong acidity can be preserved with stability for a long period of time, and an organic electroluminescent device having a layer formed of a hole transport material which has been preserved by the preservation method.

In order to achieve the object, the present invention is directed to a method for preserving an organic polymeric material, wherein an organic polymeric material which exhibits strong acidity is preserved with it being dissolved or dispersed in a liquid mainly comprised of water. The method is characterized in that the organic polymeric material is preserved with it being dissolved or dispersed in the liquid so that a concentration thereof is 2 wt %, and a pH (at 25° C.) of the thus obtained liquid is measured and then adjusted so as to be to be higher than the measured pH (at 25° C.).

According to the preserving method of the present invention, even if the organic polymeric material is preserved for a long period of time, it is possible to prevent or suppress a change in a molecular structure thereof with the lapse of time.

In the present invention, it is preferred that a pH (at 25° C.) of the liquid before the pH adjustment is 2.2 or lower. The method for preserving an organic polymeric material according to the present invention is especially suitable for long-term preservation of such an organic polymeric material that exhibits very strong acidity.

Further, it is also preferred that a pH (at 25° C.) of the liquid after the pH adjustment is in the range of 2.5 to 7.5. By adjusting the pH of the liquid containing a strongly acidic material to be preserved to a value within the above range prior to the preservation of the organic polymeric material, it is possible to reliably prevent or suppress a change in the molecular structure of the organic polymeric material with the lapse of time.

In the present invention, it is preferred that the pH (25° C.) of the liquid is adjusted by adding a pH adjuster to the liquid. This makes it possible to carry out pH adjustment of the liquid relatively easily.

In this case, it is also preferred that the pH adjuster contains substantially no metallic elements. This makes it possible to prevent the entry of metallic elements (a metal simple substance, a metal ion, or a metal compound and the like) into the liquid containing a strongly acidic material to be preserved, and as a result, the deterioration of the organic polymeric material with the lapse of time due to metallic elements can be prevented.

Further, it is also preferred that the pH adjuster mainly contains NH₄Cl as a major component thereof. Since an aqueous NH₄Cl solution provides a buffering action, the use of a pH adjuster mainly containing NH₄Cl makes it possible to carry out pH adjustment of the liquid more easily with high precision.

Further, in the present invention, it is also preferred that a pH (25° C.) of the liquid is adjusted by diluting the liquid with a diluent mainly containing water. This makes it possible to carry out pH adjustment of the liquid relatively easily.

In this case, it is preferred that the diluent mainly contains at least one of pure water, distilled water and RO water. The use of a diluent containing such kind of water as a major component makes it possible to prevent the entry of metallic elements into the liquid containing a strongly acidic material to be preserved, and as a result, the deterioration of the organic polymeric material with the lapse of time due to metallic elements can be prevented.

Furthermore, in the present invention, it is also preferred that a pH of the liquid is adjusted by removing hydrogen ions from the liquid using a means for removing hydrogen ions. This also makes it possible to carry out pH adjustment of the liquid relatively easily.

In this case, it is preferred that the removal of hydrogen ions by the hydrogen ions removing means is carried out by converting hydrogen ions into hydrogen gas. This method has an advantage that the need for considering the influence of additives for use in the pH adjustment and the need for operation such as concentration prior to the use of the organic polymeric material preserved are not required.

Further, in the present invention, it is preferred that a temperature of the organic polymeric material during the preservation is in the range of 15 to 40° C. This makes it possible to prevent the organic polymeric material from being precipitated due to the lowering of the solubility thereof and from being settled down due to a change in the dispersion state thereof. Further, it is also possible to prevent liberation of hydrogen ions from the organic polymeric material during preservation.

Furthermore, in the present invention, it is also preferred that the organic polymeric material is preserved with it being shut off from the outside air. This makes it possible to prevent the entry of foreign substances into the liquid during preservation.

Moreover, in the present invention, it is also preferred that the organic polymeric material is preserved with it being shut off from lights. This makes it possible to prevent the organic polymeric material from being deteriorated with the lapse of time due to light (especially, ultraviolet rays) during preservation.

Moreover, in the present invention, it is also preferred that the organic polymeric material contains at least one of a sulfone group, a carboxyl group and a phenolic hydroxyl group. Since a high concentration of hydrogen ions is liberated from such functional groups due to their very high acid dissociation constants, the method of the present invention is especially effective at preserving organic polymeric materials containing such functional groups.

Moreover, in the present invention, it is also preferred that the organic polymeric material is a hole transport material having a function of transporting holes. In a hole transport material, the molecular structure thereof (a property resulting from a unique spread of electron cloud thereof) has a large influence on its own hole transport ability, and therefore it is particularly suitable to apply the present invention to the hold transport material to prevent or suppress a change in the molecular structure of the hole transport material with the lapse of time so that the lowering or loss of the hole transport ability of the hole transport material can be reliably prevented.

In this case, it is preferred that the hole transport material is poly(3,4-ethylenedioxythiophene/styrenesulfonic acid). The method of the present invention is effective at preserving poly(3,4-ethylenedioxythiophene/styrenesulfonic acid) since it has portions (that is, C—O bonds) which are susceptible to attack by hydrogen ions.

Another aspect of the present invention is directed to an organic electroluminescent device having a layer mainly formed of the hole transport material which has been preserved by the method for preserving an organic polymeric material as described above. This makes it possible to obtain an organic electroluminescent device that has excellent light-emission luminance or the like.

The above described and other objects, structures and advantages of the present invention will be more apparent when the following detailed description of the present invention will be considered taken in conjunction with the Examples and the appended drawings.

### BRIEF DESCRIPTION OF DRAWINGS

FIG. 1 is a cross-sectional view which shows an example of an organic EL device.

FIG. 2 is a graph which shows an amount of ethylene glycol generated in each of the dispersion liquids of Examples 1 to 4 and Comparative Example after being preserved for one month, three months, and five months, respectively.

FIG. 3 is a graph which shows a light-emission luminance (a relative value) of each of organic EL devices manufactured in Examples 1 to 4 and Comparative Example.

### BEST MODE FOR CARRYING OUT THE INVENTION

<Method for Preserving Organic Polymeric Material>

First, a method for preserving an organic polymeric material according to the present invention will be described. In this regard, it is to be noted that the word “pH” in the following description refers to a pH at a temperature of 25° C. unless otherwise specified.

The method for preserving an organic polymeric material according to the present invention is a method for preserving an organic polymeric material that exhibits (shows) strong acidity (hereinafter, referred to as a “strongly acidic material”), in which the strongly acidic material is preserved with it being dissolved or dispersed in a liquid mainly comprised of water. Specifically, a strongly acidic material to be preserved is dissolved or dispersed in a liquid mainly comprised of water so that the concentration thereof is 2 wt %, and the pH of the thus obtained liquid is measured and is then adjusted to be higher than the pH at the measurement. In such a state, the strongly acidic material is preserved.

Here, if a strongly acidic material is preserved as a solution or a dispersion liquid for a long period of time without carrying out pH adjustment, H⁺ ions (hydrogen ions) are liberated in the liquid (that is, in a solvent or a dispersion medium) in a high concentration, and such a high concentration of H⁺ ions changes (e.g., decomposes) the molecular structure of the strongly acidic material with the lapse of time. In order to solve such a problem, the present inventors have made extensive researches and studies, and as a result, they have found that a change in the molecular structure of a strongly acidic material with the lapse of time during preservation can be prevented or reduced by adjusting the pH of a liquid containing the strongly acidic material to be higher prior to the preservation of the strongly acidic material. The present inventors have also found that in a case where the pH of a strongly acidic material in a liquid state is 2.2 or lower (especially, 1.8 or lower) before the pH adjustment, the molecular structure thereof is significantly changed with the lapse of time. From these findings, it can be said that the method for preserving an organic polymeric material according to the present invention is suitable for long-term preservation of such a strongly acidic material that exhibits very strong acidity.

The pH of a liquid containing a strongly acidic material to be preserved after pH adjustment (hereinafter, referred to as a “liquid after adjustment”) can be appropriately set according to the pH of the liquid containing the strongly acidic material to be preserved before pH adjustment (hereinafter, referred to as a “liquid before adjustment”). In a case where the pH of the liquid before adjustment lies within the range mentioned above, the pH of the liquid after adjustment is preferably in the range of about 2.5 to 7.5, more preferably in the range of about 3.0 to 5.0. By adjusting the pH of a liquid containing a strongly acidic material to be preserved to a value within the above range prior to the preservation of the strongly acidic material, it is possible to reliably prevent or suppress a change in the molecular structure of the strongly acidic material with the lapse of time. In this regard, it is to be noted that in a case where a strongly acidic material is preserved at a relatively high pH exceeding a neutral value (that is, at a pH within an alkaline range), there is a fear that the strongly acidic material undergoes a change in its molecular structure depending on the kind thereof or the like due to the influence of alkali ions such as OH⁻ ions.

The method for preserving an organic polymeric material according to the present invention can be applied to various strongly acidic materials. In particular, it is preferably applied to strongly acidic materials containing at least one of a sulfone group (—SO₃H), a carboxyl group (—COOH), and a phenolic hydroxyl group (—OH). Since a high concentration of H⁺ ions is liberated from such functional groups due to their very high acid dissociation constants, the method of the present invention is especially effective at preserving strongly acidic materials containing such functional groups.

Further, there are known strongly acidic materials having various functions (that is, they are functional materials). Among them, the method of the present invention is preferably applied to hole transport materials having the function of transporting holes. In a hole transport material, the molecular structure thereof (a property resulting from a unique spread of electron cloud thereof) has a large influence on its own hole transport ability. According to the method of the present invention, it is possible to prevent or suppress a change in the molecular structure of the hole transport material with the lapse of time so that the lowering or loss of the hole transport ability of the hole transport material can be reliably prevented.

In view of the aspects described above, among various strongly acidic materials to be preserved, the method of the present invention is particularly preferably applied to poly(3,4-ethylenedioxythiophene/styrenesulfonic acid) (hereinafter, abbreviated as “PEDT/PSS”) represented by the following chemical formula 1.

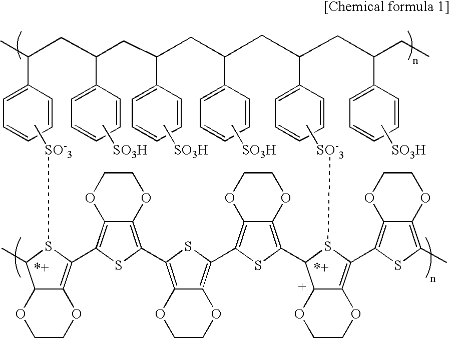

PEDT of PEDT/PSS has portions (that is, C—O bonds) which are susceptible to attack by H⁺ ions. When H⁺ ions exist in high concentrations, the C—O bonds are cleaved (that is, PEDT/PSS are subjected to acid hydrolysis) so that ethylene glycol is released from PEDT/PSS, thus changing the molecular structure of PEDT/PSS. As a result, the hole transport ability of PEDT/PSS is extremely lowered, and therefore, for example, an organic EL device manufactured in a manner described later using such PEDT/PSS cannot have satisfactory light-emission luminance or the like. On the other hand, in a case where PEDT/PSS is preserved after pH adjustment is carried out, a change in the molecular structure of PEDT/PSS with the lapse of time resulting from H⁺ ions is prevented or suppressed. Therefore, an organic EL device manufactured using such PEDT/PSS as a hole transport material can have good light-emission luminance or the like.

In the present invention, water or a liquid mixture containing water as a major component and another liquid is used for preservation of a strongly acidic material. Examples of water that can be used include pure water (or ultrapure water), distilled water, and RO water, and they can be used singly or in combination of two or more of them. Examples of a liquid to be used in combination with water include nitric acid, sulfuric acid, hydrochloric acid, acetic acid, oxygenated water, ammonia water, methanol, ethanol, isopropanol, ethyl ether, methyl ethyl ketone (MEK), acetone, 1,4-dioxane, tetrahydrofuran (THF), ethylene glycol, diethylene glycol, glycerin, ethylene glycol monomethyl ether (methyl cellosolve), ethylene glycol monoethyl ether (ethyl cellosolve), ethylene glycol monobutyl ether (butyl cellosolve), ethylene glycol monoethyl ether acetate (cellosolve acetate), N,N-dimethylformamide (DMF), N,N-dimethylacetamide (DMA), dimethylamine, diethylamine, methyl acetate, and acetonitrile.

The pH of a liquid containing a strongly acidic material to be preserved can be adjusted by, for example, (I) a method in which a pH adjuster is added to the liquid, (II) a method in which the liquid is diluted with a diluent mainly containing water, or (III) a method in which H⁺ ions in the liquid are removed using a means for removing H⁺ ions. According to such a method, it is possible to carry out pH adjustment of the liquid relatively easily. In this regard, it is to be noted that these methods may be used singly or in combination of two or more of them.

Hereinbelow, the methods (I) to (III) will be described.

(I): pH Adjustment Using pH Adjuster

As a pH adjuster to be used in this method, a substance which functions as a base for a strongly acidic material to be preserved, that is, an acidic substance having a smaller acid dissociation constant as compared with the strongly acidic material, or a basic substance can be mentioned.

Further, it is preferred that the pH adjuster contains substantially no metallic elements. In this regard, it is to be noted that such metallic elements include those in any form such as a metal simple substance, a metal ion, or a metal compound. The use of such a pH adjuster makes it possible to prevent the entry of metallic elements into a liquid containing a strongly acidic material to be preserved, and as a result, the deterioration of the strongly acidic material with the lapse of time due to metallic elements can be prevented. For these reasons, preferred examples of the pH adjuster include NH₄Cl, NH₃, NH₄OH, organic amines and the like. They may be used singly or in combination of two or more of them. Among them, one mainly containing NH₄Cl is particularly preferable as the pH adjuster. Since an aqueous NH₄Cl solution provides a buffering action, the use of a pH adjuster mainly containing NH₄Cl makes it possible to carry out pH adjustment of the liquid more easily with high precision.

(II): pH Adjustment by Dilution

As a diluent to be used in this method, one mainly containing water can be mentioned. It is preferred that the water contains substantially no metallic elements for the same reason as that described with reference to the method (I).

Further, it is preferred that the water mainly contains at least one of pure water, distilled water and RO water. The use of such a diluent containing water as a major component makes it possible to prevent the entry of metallic elements into a liquid containing a strongly acidic material to be preserved, and as a result, the deterioration of the strongly acidic material with the lapse of time due to metallic elements can be prevented.

Further, in a case where this method is employed for pH adjustment, it is preferred that concentration of the liquid is carried out at the termination of preservation, that is, prior to the use of the strongly acidic material preserved so that the strongly acidic material may be contained in the liquid in an appropriate amount. Any method can be employed as a method for concentration, and for example, an ultrafiltration method (dialysis method) can be preferably employed.

(III): pH Adjustment by the Removal of H⁺ Ions

Examples of a method for removing H⁺ ions include a method in which an electrode is used as a means for removing H⁺ ions to convert H⁺ ions into H₂ (hydrogen gas) through a reverse reaction of the electrolysis of water, and a method in which an ion-exchange resin is used as a means for removing H⁺ ions to adsorb H⁺ ions thereto to remove them. Among these methods, the method in which an electrode is used to convert H⁺ ions into H₂ is preferably employed. Such a method has an advantage that the need for considering the influence of additives for use in pH adjustment and the need for operation such as concentration prior to the use of a strongly acidic material preserved are not required.

A liquid containing a strongly acidic material to be preserved is subjected to pH adjustment by the method as described above, and is then preserved as it is. The temperature of the strongly acidic material (that is, the temperature of the liquid after adjustment) during preservation is not limited to any specific value, but is preferably in the range of about 5 to 40° C., more preferably in the range of about 15 to 30° C. If the temperature of the strongly acidic material during preservation is too low, there is a fear that the strongly acidic material is precipitated due to the lowering of the solubility thereof or the strongly acidic material is settled down due to a change in the dispersion state thereof. On the other hand, if the temperature of the strongly acidic material during preservation is too high, there is a fear that H⁺ ions are liberated from the strongly acidic material during preservation so that the structure of the strongly acidic material is changed.

Further, it is preferred that the liquid after adjustment is preserved with it being shut off from the outside air. This makes it possible to prevent the entry of foreign substances into the liquid (that is, into the strongly acidic material) during preservation.

Furthermore, it is also preferred that the liquid after adjustment is preserved with it being shut off from light. This makes it possible to prevent the strongly acidic material from being deteriorated with the lapse of time due to light (especially, ultraviolet rays) during preservation.

<Organic EL Device>

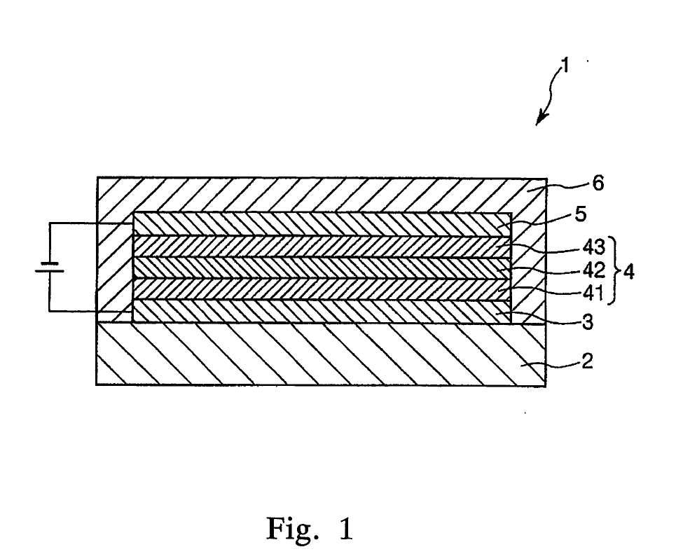

Next, an organic EL device (organic electroluminescent device) having a layer (hole transport layer) mainly formed of a hole transport material (PEDT/PSS) which has been preserved by the method for preserving an organic polymeric material according to the present invention will be described. FIG. 1 is a cross-sectional view which shows an example of an organic EL device.

An organic EL device 1 shown in FIG. 1 includes a transparent substrate 2, an anode 3 provided on the substrate 2, an organic EL layer 4 provided on the anode 3, a cathode 5 provided on the organic EL layer 4, and a protection layer 6 provided so as to cover these layers 3, 4 and 5. The substrate 2 serves as a support of the organic EL device 1, and the layers described above are formed on this substrate 2.

As a constituent material of the substrate 2, a material having a light transmitting property and a good optical property can be used. Examples of such a constituent material include various resin materials such as polyethylene terephthalate, polyethylene naphthalate, polypropylene, cycloolefin polymer, polyamide, polyether sulfone, polymethyl methacrylate, polycarbonate, and polyarylate, various glass materials, and the like. These materials can be used singly or in combination of two or more of them. The thickness of the substrate 2 is not limited to any specific value, but is preferably in the range of about 0.1 to 30 mm, more preferably in the range of about 0.1 to 10 mm.

The anode 3 is an electrode which injects holes into the organic EL layer 4 (that is, into a hole transport layer 41 described later). Further, this anode 3 is made substantially transparent (which includes colorless and transparent, colored and transparent, or translucent) so that light emission from the organic EL layer 4 (that is, from a light emitting layer 42 described later) can be visually identified.

From such a viewpoint, a material having a high work function, excellent conductivity and a light transmitting property is preferably used as a constituent material of the anode 3 (hereinafter, referred to as “anode material”). Examples of such an anode material include oxides such as ITO (Indium Tin Oxide), SnO₂, Sb-containing SnO₂, and Al-containing ZnO, Au, Pt, Ag, Cu, and alloys containing two or more of them. These materials can be used singly or in combination of two or more of them.

The thickness of the anode 3 is not limited to any specific value, but is preferably in the range of about 10 to 200 nm, more preferably in the range of about 50 to 150 nm. If the thickness of the anode 3 is too thin, there is a fear that a function as the anode 3 is not sufficiently exhibited. On the other hand, if the thickness of the anode 3 is too thick, there is a fear that light transmittance is significantly lowered depending on the kind of anode material used, or the like, thus resulting in an organic EL device that is not suitable for practical use.

In this regard, it is to be noted that conductive resin materials such as polythiophene, polypyrrole, and the like can be used for the anode material, for example.

On the other hand, the cathode 5 is an electrode which injects electrons into the organic EL layer 4 (that is, into an electron transport layer 43 described later). As a constituent material of the cathode 5 (hereinafter, referred to as “cathode material”), a material having a low work function is preferably used. Examples of such a cathode material include Li, Mg, Ca, Sr, La, Ce, Er, Eu, Sc, Y, Yb, Ag, Cu, Al, Cs, Rb, Au and alloys containing two or more of them. These materials can be used singly or in combination of two or more of them. Particularly, in a case where an alloy is used as the cathode material, an alloy containing a stable metallic element such as Ag, Al, or Cu, specifically an alloy such as MgAg, AlLi, or CuLi is preferably used. The use of such an alloy as the cathode material makes it possible to improve the electron injection efficiency and stability of the cathode 5.

The thickness of the cathode 5 is preferably in the range of about 1 nm to 1 μm, more preferably in the range of about 100 to 400 nm. If the thickness of the cathode 5 is too thin, there is a fear that a function as the cathode 5 is not sufficiently exhibited. On the other hand, if the cathode 5 is too thick, there is a fear that the light emitting efficiency of the organic EL device 1 is lowered. Between the anode 3 and the cathode 5, there is provided the organic EL layer 4. The organic EL layer 4 includes the hole transport layer 41, the light emitting layer 42, and the electron transport layer 43. These layers are formed on the anode 3 in this order.

The hole transport layer 41 has the function of transporting holes, which are injected from the anode 3, to the light emitting layer 42. The hole transport layer 41 is formed using PEDT/PSS (that is a hole transport material), which has been preserved by the method for preserving an organic polymeric material according to the present invention, as a main component. PEDT/PSS has an especially high hole transport ability, thus resulting in an organic EL device 1 that has excellent light-emission luminance or the like.

It should be noted that the hole transport layer 41 may be formed by the combination of PEDT/PSS and one or more of the following hole transport materials.

Examples of a hole transport material to be used in combination with PEDT/PSS include: arylcycloalkane-based compounds such as 1,1-bis(4-di-para-triaminophenyl)cyclohexane, and 1,1′-bis(4-di-para-tolylaminophenyl)-4-phenyl-cyclohexane; arylamine-based compounds such as 4,4′,4″-trimethyltriphenylamine, N,N,N′,N′-tetraphenyl-1,1′-biphenyl-4,4′-diamine, N,N′-diphenyl-N,N′-bis(3-methylphenyl)-1,1′-biphenyl-4,4′-diamine(TPD1), N,N′-diphenyl-N,N′-bis(4-methoxyphenyl)-1,1′-biphenyl-4,4′-diamine(TPD2), N,N,N′,N′-tetrakis(4-methoxyphenyl)-1,1′-biphenyl-4,4′-diamine(TPD3), N,N′-di(1-naphthyl)-N,N′-diphenyl-1,1′-biphenyl-4,4′-diamine(α-NPD), and TPTE; phenylenediamine-based compounds such as N,N,N′,N′-tetraphenyl-para-phenylenediamine, N,N,N′,N′-tetra(para-tolyl)-para-phenylenediamine, and N,N,N′,N′-tetra(meta-tolyl)-meta-phenylenediamine(PDA); carbazole-based compounds such as carbazole, N-isopropylcarbazole, and N-phenylcarbazole; stilbene-based compounds such as stilbene, and 4-di-para-tolylaminostilbene; oxazole-based compounds such as OxZ; triphenylmethane-based compounds such as triphenylmethane, and m-MTDATA; pyrazoline-based compounds such as 1-phenyl-3-(para-dimethylaminophenyl)pyrazoline; benzine(cyclohexadiene)-based compounds; triazole-based compounds such as triazole; imidazole-based compounds such as imidazole; oxadiazole-based compounds such as 1,3,4-oxadiazole, and 2,5-di(4-dimethylaminophenyl)-1,3,4-oxadiazole; anthracene-based compounds such as anthracene, and 9-(4-diethylaminostyryl)anthracene; fluorenone-based compounds such as fluorenone, 2,4,7-trinitro-9-fluorenone, and 2,7-bis(2-hydroxy-3-(2-chlorophenylcarbamoyl)-1-naphthylazo) fluorenone; aniline-based compounds such as polyaniline; silane-based compounds; thiophene-based compounds such as polythiophene, and poly(thiophenevinylene); pyrrole-based compounds such as poly(2,2′-thienylpyrrole), and 1,4-dithioketo-3,6-diphenyl-pyrrolo-(3,4-c)pyrrolopyrrole; florene-based compounds such as florene; porphyrin-based compounds such as porphyrin, and metal tetraphenylporphyrin; quinacridon-based compounds such as quinacridon; metallic or non-metallic phthalocyanine-based compounds such as phthalocyanine, copper phthalocyanine, tetra(t-butyl)copper phthalocyanine, and iron phthalocyanine; metallic or non-metallic naphthalocyanine-based compounds such as copper naphthalocyanine, vanadyl naphthalocyanine, and monochlorogallium naphthalocyanine; and benzidine-based compounds such as N,N′-di(naphthalene-1-yl)-N,N′-diphenyl-benzidine, and N,N,N′,N′-tetraphenylbenzidine. All of these compounds have a high hole transport ability.

Further, these compounds can be used as a monomer or an oligomer (which is a low-molecular hole transport material), or as a prepolymer or a polymer containing these compounds in a main chain or a side chain thereof (which is a high-molecular hole transport material). The combination of PEDT/PSS and such a low-molecular hole transport material has an advantage that it is possible to easily form a dense hole transport layer 41 having an excellent hole transport ability by means of various application methods such as an ink-jet printing method and the like.

In a case where PEDT/PSS and another hole transport material are used together, another hole transport material may be previously mixed with a dispersion liquid before preservation or may be preserved under conditions different from those for PEDT/PSS and then be mixed with PEDT/PSS just prior to use (that is, just prior to formation of the hole transport layer 41).

The thickness of the hole transport layer 41 is not limited to any specific value, but is preferably in the range of about 10 to 150 nm, more preferably in the range of about 50 to 100 nm. If the thickness of the hole transport layer 41 is too thin, there is a fear that a pin hole is produced. On the other hand, if the hole transport layer 41 is too thick, there is a fear that the transmittance of the hole transport layer 41 is lowered so that the chromaticity (hue) of luminescent color of the organic EL device 1 is changed.

The electron transport layer 43 has the function of transporting electrons, which are injected from the cathode 5, to the light emitting layer 42.

Examples of a constituent material of the electron transport layer 43 (hereinafter, referred to as “electron transport material”) include: benzene-based compounds (starburst-based compounds) such as 1,3,5-tris[(3-phenyl-6-tri-fluoromethyl)quinoxaline-2-yl]benzene(TPQ1), and 1,3,5-tris[{3-(4-t-butylphenyl)-6-trisfluoromethyl}quinoxaline-2-yl]benzene (TPQ2); naphthalene-based compounds such as naphthalene; phenanthrene-based compounds such as phenanthrene; chrysene-based compounds such as chrysene; perylene-based compounds such as perylene; anthracene-based compounds such as anthracene; pyrene-based compounds such as pyrene; acridine-based compounds such as acridine; stilbene-based compounds such as stilbene; thiophene-based compounds such as BBOT; butadiene-based compounds such as butadiene; coumarin-based compounds such as coumarin; quinoline-based compounds such as quinoline; bistyryl-based compounds such as bistyryl; pyrazine-based compounds such as pyrazine and distyrylpyrazine; quinoxaline-based compounds such as quinoxaline; benzoquinone-based compounds such as benzoquinone and 2,5-diphenyl-para-benzoquinone; naphthoquinone-based compounds such as naphthoquinone; anthraquinone-based compounds such as anthraquinone; oxadiazole-based compounds such as oxadiazole, 2-(4-biphenylyl)-5-(4-t-butylphenyl)-1,3,4-oxadiazole (PBD), BMD, BND, BDD, and BAPD; triazole-based compounds such as triazole, and 3,4,5-triphenyl-1,2,4-triazole; oxazole-based compounds; anthrone-based compounds such as anthrone; fluorenone-based compounds such as fluorenone, and 1,3,8-trinitro-fluorenone (TNF); diphenoquinone-based compound such as diphenoquinone, and MBDQ; stilbenequinone-based compounds such as stilbenequinone, and MBSQ; anthraquinodimethane-based compounds; thiopyran dioxide-based compounds; fluorenylidenemethane-based compounds; diphenyldicyanoethylene-based compounds; florene-based compounds such as florene; metallic or non-metallic phthalocyanine-based compounds such as phthalocyanine, copper phthalocyanine, and iron phthalocyanine; and various metal complexes such as (8-hydroxyquinoline)aluminum (Alq₃), and complexes having benzooxazole or benzothiazole as a ligand. These compounds may be used singly or in combination of two or more of them. The thickness of the electron transport layer 43 is not limited to any specific value, but is preferably in the range of about 1 to 100 nm, more preferably in the range of about 20 to 50 nm. If the thickness of the electron transport layer 43 is too thin, there is a fear that a pin hole is produced, causing a short-circuit. On the other hand, if the electron transport layer 43 is too thick, there is a fear that the value of resistance becomes high.

When a current flows between the anode 3 and the cathode 5 (that is, a voltage is applied across the anode 3 and the cathode 5), holes are moved in the hole transport layer 41 and electrons are moved in the electron transport layer 43, and the holes and the electrons are then recombined in the light emitting layer 42. Then, in the light emitting layer 42, excitons are produced by energy released upon the recombination, and the excitons release energy (in the form of fluorescence or phosphorescence) or emit light when returning to the ground state.

Any material can be used as a constituent material of the light emitting layer 42 (hereinafter, referred to as “light emitting material”) so long as it can provide a field where holes can be injected from the anode 3 and electrons can be injected from the cathode 5 during the application of a voltage to allow the holes and the electrons to be recombined. Such light emitting materials include various low-molecular light emitting materials and various high-molecular light emitting materials (which will be mentioned below). These materials may be used singly or in combination of two or more of them.

In this regard, it is to be noted that the use of a low-molecular light emitting material makes it possible to obtain a dense light emitting layer 42, thereby improving the light emitting efficiency of the light emitting layer 42. Further, since such a high-molecular light emitting material is relatively easily dissolved in a solvent, it is possible to easily form the light emitting layer 42 by means of various application methods such as an ink-jet printing method and the like. Furthermore, if the low-molecular light emitting material and the high-molecular light emitting material are used together, it is possible to obtain the synergistic effect resulted from the effect of the low-molecular light emitting material and the effect of the high-molecular light emitting material. That is, it is possible to obtain an effect that a dense light emitting layer 42 having an excellent light emitting efficiency can be easily formed by means of various application methods such as an ink-jet printing method and the like.

Examples of such a low-molecular light emitting material include: benzene-based compounds such as distyrylbenzene (DSB), and diaminodistyrylbenzene (DADSB); naphthalene-based compounds such as naphthalene, and Nile red; phenanthrene-based compounds such as phenanthrene; chrysene-based compounds such as chrysene, and 6-nitrochrysene; perylene-based compounds such as perylene, and N,N′-bis(2,5-di-t-butylphenyl)-3,4,9,10-perylene-di-carboxyimide(BPPC); coronene-based compounds such as coronene; anthracene-based compounds such as anthracene, and bisstyrylanthracene; pyrene-based compounds such as pyrene; pyran-based compounds such as 4-(di-cyanomethylene)-2-methyl-6-(para-dimethylaminostyryl)-4H-pyran(DCM); acridine-based compounds such as acridine; stilbene-based compounds such as stilbene; thiophene-based compounds such as 2,5-dibenzooxazolethiophene; benzooxazole-based compounds such as benzooxazole; benzoimidazole-based compounds such as benzoimidazole; benzothiazole-based compounds such as 2,2′-(para-phenylenedivinylene)-bisbenzothiazole; butadiene-based compounds such as bistyryl(1,4-diphenyl-1,3-butadiene), and tetraphenylbutadiene; naphthalimide-based compounds such as naphthalimide; coumarin-based compounds such as coumarin; perynone-based compounds such as perynone; oxadiazole-based compounds such as oxadiazole; aldazine-based compounds; cyclopentadiene-based compounds such as 1,2,3,4,5-pentaphenyl-1,3-cyclopentadiene(PPCP); quinacridon-based compounds such as quinacridon, and quinacridon red; pyridine-based compounds such as pyrrolopyridine, and thiadiazolopyridine; spiro compounds such as 2,2′,7,7′-tetraphenyl-9,9′-spirobifluorene; metallic or non-metallic phthalocyanine-based compounds such as phthalocyanine (H₂Pc), and copper phthalocyanine; florene-based compounds such as florene; and various metal complexes such as (8-hydroxyquinoline) aluminum (Alq₃), tris(4-methyl-8-quinolinolate) aluminum (III) (Almq₃), (8-hydroxyquinoline)zinc(Znq₂), (1,10-phenanthroline)-tris-(4,4,4-trifluoro-1-(2-thienyl)-butan-1,3-dionate)europium(III) (Eu(TTA)₃(phen)), fac-tris(2-phenylpyridine)iridium(Ir(ppy)₃), and (2,3,7,8,12,13,17,18-octaethyl-21H,23H-porphin) platinum (II).

Examples of such a high-molecular light emitting material include: polyacetylene-based compounds such as trans-type polyacetylene, cis-type polyacetylene, poly(di-phenylacetylene) (PDPA), and poly(alkyl, phenylacetylene)(PAPA); polyparaphenylenevinylene-based compounds such as poly(para-phenylenevinylene)(PPV), poly(2,5-dialkoxy-para-phenylenevinylene)(RO—PPV), cyano-substituted-poly(para-phenylenevinylene)(CN—PPV), poly(2-dimethyloctylsilyl-para-phenylenevinylene)(DMOS—PPV), and poly(2-methoxy-5-(2′-ethylhexoxy)-para-phenylenevinylene) (MEH—PPV); polythiophene-based compounds such as poly(3-alkylthiophene) (PAT), and poly(oxypropylene) triol (POPT); polyfluorene-based compounds such as poly(9,9-dialkylfluorene) (PDAF), α,ω-bis[N,N′-di(methylphenyl)aminophenyl]-poly[9,9-bis(2-ethylhexyl)fluorene-2,7-diyl] (PF2/6am4), and poly(9,9-dioctyl-2,7-divinylenefluorenyl-alt-co(anthracene-9,10-diyl); polyparaphenylene-based compounds such as poly(para-phenylene) (PPP), and poly(1,5-dialkoxy-para-phenylene) (RO—PPP); polycarbazole-based compound such as poly(N-vinylcarbazole) (PVK); and polysilane-based compounds such as poly(methylphenylsilane) (PMPS), poly(naphthylphenylsilane) (PNPS), and poly(biphenylylphenylsilane) (PBPS).

The thickness of the light emitting layer 42 is not limited to any specific value, but is preferably in the range of about 10 to 150 nm, more preferably in the range of about 50 to 100 nm. By setting the thickness of the light emitting layer 42 to a value within the above range, recombination of holes and electrons efficiently occurs, thereby enabling the light emitting efficiency of the light emitting layer 42 to be further improved.

Although, in the present embodiment, each of the light emitting layer 42, the hole transport layer 41, and the electron transport layer 43 is separately provided, they may be formed into a hole-transportable light emitting layer which combines the hole transport layer 41 and the light emitting layer 42 or an electron-transportable light emitting layer which combines the electron transport layer 43 and the light emitting layer 42. In this case, an area in the vicinity of the interface between the hole-transportable light emitting layer and the electron transport layer 43 or an area in the vicinity of the interface between the electron-transportable light emitting layer and the hole transport layer 41 functions as the light emitting layer 42.

Further, in a case where the hole-transportable light emitting layer is used, holes injected from an anode into the hole-transportable light emitting layer are trapped by the electron transport layer, and in a case where the electron-transportable light emitting layer is used, electrons injected from a cathode into the electron-transportable light emitting layer are trapped in the electron-transportable light emitting layer. In both cases, there is an advantage that the recombination efficiency of holes and electrons can be improved. Furthermore, between the adjacent layers in the layers 3, 4, and 5, any additional layer may be provided according to its purpose. For example, a hole injecting layer may be provided between the hole transport layer 41 and the anode 3, or an electron injecting layer may be provided between the electron transport layer 43 and the cathode 5. In such a case where the organic EL device 1 includes the hole injecting layer, the hole injecting layer may be formed of a hole transport material which has been preserved by the method for preserving an organic polymeric material according to the present invention. On the other hand, in a case where the organic EL device 1 includes the electron injecting layer, not only the electron transport material mentioned above but also alkali halide such as LiF and the like may be employed for the electron injecting layer.

The protection layer 6 is provided so as to cover the layers 3, 4 and 5 constituting the organic EL device 1. This protection layer 6 has the function of hermetically sealing the layers 3, 4 and 5 constituting the organic EL device 1 to shut off oxygen and moisture. By providing such a protection layer 6, it is possible to obtain the effect of improving the reliability of the organic EL device 1 and the effect of preventing the alteration and deterioration of the organic EL device 1. Examples of a constituent material of the protection layer 6 include Al, Au, Cr, Nb, Ta and Ti, alloys containing them, silicon oxide, various resin materials, and the like. In this regard, it is to be noted that in a case where a conductive material is used as a constituent material of the protection layer 6, it is preferred that an insulating film is provided between the protection layer 6 and each of the layers 3, 4 and 5 to prevent a short circuit therebetween, if necessary.

This organic EL device 1 can be used for a display, for example, but it can also be used for various optical purposes such as a light source and the like. In a case where the organic EL device 1 is applied to a display, the drive system thereof is not particularly limited, and either of an active matrix system or a passive matrix system may be employed.

The organic EL device 1 as described above can be manufactured in the following manner, for example.

<1> First, the substrate 2 is prepared, and the anode 3 is then formed on the substrate 2. The anode 3 can be formed by, for example, chemical vapor deposition (CVD) such as plasma CVD, thermal CVD, or laser CVD, dry plating such as vacuum deposition, sputtering, or ion plating, wet plating such as electrolytic plating, immersion plating, or electroless plating, sputtering, a sol-gel method, a MOD method, bonding of a metallic foil, or the like.

<2> Next, the hole transport layer 41 is formed on the anode 3. The hole transport layer 41 can be formed by, for example, applying the solution or dispersion liquid of the hole transport material as mentioned above on the anode 3. In the application of the hole transport material, various application methods such as a spin coating method, a casting method, a micro gravure coating method, a gravure coating method, a bar coating method, a roll coating method, a wire-bar coating method, a dip coating method, a spray coating method, a screen printing method, a flexographic printing method, an offset printing method, an ink-jet printing method, and the like can be employed. According to such an application method, it is possible to relatively easily form the hole transport layer 41.

If necessary, an obtained coating may be subjected to heat treatment, for example, in the atmosphere or an inert atmosphere or under a reduced pressure (or under vacuum). This makes it possible to dry the coating (that is the removal of a solvent or a dispersion medium) or polymerize the hole transport material, for example. In this regard, it is to be noted that the coating may be dried without heat treatment.

Further, in a case where a low-molecular hole transport material is used, a binder (high-molecular binder) may be added to the hole transport layer material, if necessary.

As a binder, one which does not extremely inhibit charge transport and has a low absorptivity for visible radiation is preferably used. Specifically, examples of such a binder include polyethylene oxide, polyvinylidene fluoride, polycarbonate, polyacrylate, polymethyl acrylate, polymethyl methacrylate, polystyrene, polyvinyl chloride, polysiloxane, and the like, and they can be used singly or in combination of two or more of them. Alternatively, the high-molecular hole transport material as mentioned above may be used for the binder.

<3> Next, the light emitting layer 42 is formed on the hole transport layer 41. The light emitting layer 42 can be formed in the same manner as the hole transport layer 41. Namely, the light emitting layer 42 can be formed using the light emitting material mentioned above in a manner described above with reference to the hole transport layer 41.

<4> Next, the electron transport layer 43 is formed on the light emitting layer 42. The electron transport layer 43 can be formed in the same manner as the hole transport layer 41. Namely, the electron transport layer 43 can be formed using the electron transport material mentioned above in a manner described above with reference to the hole transport layer 41.

<5> Next, the cathode 5 is formed on the electron transport layer 43. The cathode 5 can be formed by, for example, vacuum deposition, sputtering, bonding of a metallic foil, or the like.

<6> Next, the protection layer 6 is formed so as to cover the cathode 3, the organic EL layer 4, and the cathode 5. The protection layer 6 can be formed (provided) by, for example, bonding a box-like protection cover constituted of the material as mentioned above by the use of various curable resins (adhesives). As for the curable resins, all of thermosetting resins, photocurable resins, reactive curable resins, and anaerobic curable resins can be used. The organic EL device 1 is manufactured through these processes as described above.

Although the method for preserving an organic polymeric material and the organic electroluminescent device according to the present invention have been described, the present invention is not limited thereto. For example, the method for preserving an organic polymeric material according to the present invention can be applied not only to the preservation of the above-mentioned organic polymeric materials that exhibits strong acidity for use in forming layers of organic electroluminescent devices but also to the preservation of organic polymeric materials that show strong acidity for use in forming electronic devices other than organic electroluminescent devices. Further, the method for preserving an organic polymeric material according to the present invention can also be applied not only to the preservation of organic polymeric materials for use in manufacturing electronic devices but also to the preservation of organic polymeric materials that show strong acidity for use in various purposes.

### EXAMPLES

Next, actual examples of the present invention will be described.

### Example 1

PEDT/PSS (which is a hole transport material and is manufactured by Bayer Corp. under the product name of “Baytron P”) was dispersed in pure water so that the concentration thereof might be 2 wt % to prepare a dispersion liquid. Next, this dispersion liquid was passed through a dialysis membrane having a molecular-weight cut off of 3,000 to remove ethylene glycol. It should be noted that the pH (at 25° C.) of the dispersion liquid was 1.2.

Next, NH₄Cl (pH adjuster) was dissolved in pure water so that the concentration thereof was 30 wt % to prepare an aqueous NH₄Cl solution. The aqueous NH₄Cl solution was dropped into the dispersion liquid to adjust the pH (at 25° C.) of the dispersion liquid to 3.0. The dispersion liquid after pH adjustment was placed in a gastight enclosure (that is, in a state where the outside air was being shut off), and was then preserved at 25° C. in a dark place (that is, in a state where light was being shut off) for one month, three months, and five months, respectively. Then, organic EL devices were manufactured in the following manner by the use of the dispersion liquids preserved for one month, three months, and five months, respectively.

First, a transparent glass substrate, on which an anode made of ITO (Indium Tin Oxide) had been formed, was prepared. The dispersion liquid (that is, the PEDT/PSS dispersion liquid) which had been preserved was applied on the glass substrate by a spin coating method, and was then dried by heating to form a hole transport layer having an average thickness of 50 nm. Next, poly[9,9′-dihexyl-2,7-(2-cyanovinylene)fluorenylene] (which is a light emitting material and has a weight average molecular weight of 120,000) was dissolved in toluene so that the concentration thereof might be 2 wt % to prepare a light emitting material solution. The light emitting material solution was applied on the hole transport layer by a spin coating method, and was then dried by heating to form a light emitting layer having an average thickness of 50 nm.

Next, 3,4,5-triphenyl-1,2,4-triazole (which is an electron transport material) was evaporated onto the light emitting layer by vacuum evaporation to form an electron transport layer having an average thickness of 20 nm. Then, an AlLi cathode (cathode) was formed on the electron transport layer by a vacuum evaporation method so as to have an average thickness of 300 nm. Then, a protection cover made of polycarbonate was provided so as to cover the formed layers, and was secured with an ultraviolet cure resin to secure and seal the layers. In this way, organic EL devices as shown in FIG. 1 were manufactured. It should be noted that the amount of ethylene glycol generated in each of the dispersion liquids which had been preserved for one month, three months, and five months, respectively, was measured in a manner described below prior to the manufacture of the organic EL devices.

### Example 2

Organic El devices were manufactured in the same manner as in Example 1 except that the pH (at 25° C.) of the dispersion liquid, from which ethylene glycol had been removed in the same manner as in Example 1, was adjusted to 3.0 by diluting the dispersion liquid with pure water (that is, with a diluent). It should be noted that, prior to the manufacture of the organic EL devices, each of the dispersion liquids which had been preserved was concentrated using a dialysis membrane (which is manufactured by Millipore Corp. under the product name of “Pellicon Biomax”) so that the amount of PEDT/PSS contained in the dispersion liquid was 2 wt %.

### Example 3

Organic EL devices were manufactured in the same manner as in Example 1 except that the pH (at 25° C.) of the dispersion liquid, from which ethylene glycol had been removed in the same manner as in Example 1, was adjusted to 3.0 by immersing a Pt electrode (that is, by immersing a means for removing H⁺ ions) in the dispersion liquid to convert H⁺ ions liberated in the dispersion liquid into H₂.

### Example 4

Organic EL devices were manufactured in the same manner as in Example 1 except that the pH (at 25° C.) of the dispersion liquid, from which ethylene glycol had been removed in the same manner as in Example 1, was adjusted to 7.6 by dropping dimethylamine into the dispersion liquid. It should be noted that, prior to the manufacture of the organic EL devices, the pH (at 25° C.) of each of the dispersion liquids which had been preserved was adjusted to 3.0 with an aqueous H₂SO₄ solution having a predetermined concentration.

### Comparative Example

Organic EL devices were manufactured in the same manner as in Example 1 except that pH adjustment was not carried out on the dispersion liquid, from which ethylene glycol had been removed in the same manner as in Example 1.

<Evaluation>

1. Measurement of Amount of Ethylene Glycol Generated

An amount of ethylene glycol generated in each of the dispersion liquids which had been preserved for one month, three months, and five months, respectively, was measured by H¹-NMR. From the obtained chart, a peak area derived from ethylene glycol at 3.65 ppm was determined, and then the number of ethylene glycol with respect to 100 units of polystyrenesulfonic acid was calculated from the peak area (which was an integral value).

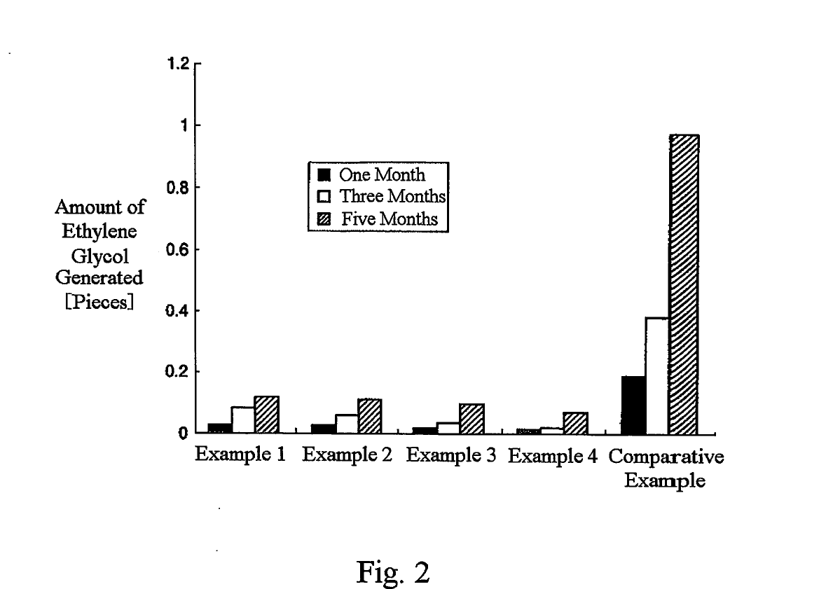

The results are shown in FIG. 2. It should be noted that the vertical axis in FIG. 2 represents the number of ethylene glycol with respect to 100 units of polystyrenesulfonic acid. As shown in FIG. 2, in all of the dispersion liquids of Examples 1 to 4 preserved for one month, three months, and five months, respectively, after pH adjustment was carried out, amounts of ethylene glycol generated were smaller as compared with the dispersion liquids of Comparative Example preserved without carrying out pH adjustment. It becomes apparent from the results that the change (that is, decomposition) of PEDT/PSS with the lapse of time can be suppressed by preserving a dispersion liquid of PEDT/PSS after pH adjustment is carried out.

2. Measurement of Light-Emission Luminance of EL Device

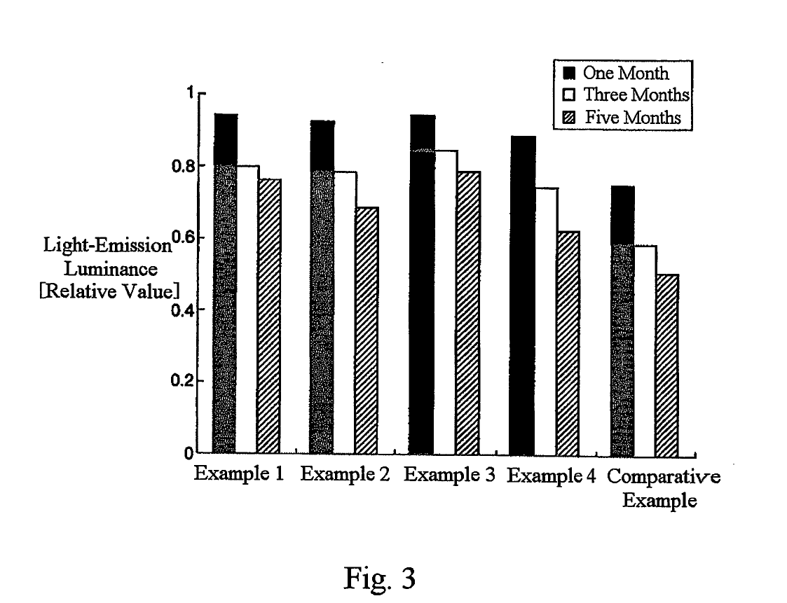

The light-emission luminance of each of the organic EL devices manufactured in Examples 1 to 4 and Comparative Example was measured by applying a voltage of 5V across the ITO electrode and the AlLi electrode. The results are shown in FIG. 3. In this regard, it should be noted that the vertical axis in FIG. 3 represents the relative value of light-emission luminance with respect to the light-emission luminance of an organic EL device manufactured in the same manner as that described above using the dispersion liquid (that is, the PEDT/PSS dispersion liquid) before preservation, wherein the light-emission luminance of such an organic EL device was measured by applying a voltage of 5V across the ITO electrode and the AlLi electrode, and the thus obtained light-emission luminance was set to “1”.

As shown in FIG. 3, all of the organic EL devices of Examples 1 to 4 manufactured using the dispersion liquids, which had been preserved for one month, three months, and five months, respectively, had higher light-emission luminance as compared with the organic EL devices of Comparative Example. It becomes apparent from the results that an organic EL device manufactured using the dispersion liquid preserved after pH adjustment is carried out can have good properties.

In this regard, it should be noted that, in all of the organic EL devices of Example 4 manufactured using the dispersion liquids preserved for one month, three months, and five months, respectively, after the pH thereof was adjusted to 7.6 in each case, there was a tendency to show lower light-emission luminance as compared with the organic EL devices of Examples 1 to 3. From the results, it can be considered that an extremely high pH of the dispersion liquid during preservation causes some change in the structure of PSS so that a doping effect resulting from the structure of PSS is lowered, which is one of causes of lowering of the hole transport ability of PEDT/PSS.

Finally, it is to be understood that many changes and additions may be made to the embodiments and Examples described above without departing from the scope and spirit of the present invention which is defined in the following claims.

Further, it is also to be understood that the present disclosure relates to subject matter contained in Japanese Patent Application No. 2003-343703 (filed on Oct. 1, 2003) which is expressly incorporated herein by reference in its entirety.

1. A method for preserving an organic polymeric material, wherein an organic polymeric material which exhibits strong acidity is preserved with it being dissolved or dispersed in a liquid mainly comprised of water, the method being characterized in that the organic polymeric material is preserved with it being dissolved or dispersed in the liquid so that a concentration thereof is 2 wt %, and a pH (at 25° C.) of the thus obtained liquid is measured and then adjusted so as to be to be higher than the measured pH (at 25° C.)

2. The method for preserving an organic polymeric material as claimed in claim 1, wherein a pH (at 25° C.) of the liquid before the pH adjustment is 2.2 or lower.

3. The method for preserving an organic polymeric material as claimed in claim 1, wherein a pH (at 25° C.) of the liquid after the pH adjustment is in the range of 2.5 to 7.5.

4. The method for preserving an organic polymeric material as claimed in claim 1, wherein the pH (25° C.) of the liquid is adjusted by adding a pH adjuster to the liquid.

5. The method for preserving an organic polymeric material as claimed in claim 4, wherein the pH adjuster contains substantially no metallic elements.

6. The method for preserving an organic polymeric material as claimed in claim 4, wherein the pH adjuster mainly contains NH₄Cl as a major component thereof.

7. The method for preserving an organic polymeric material as claimed in claim 1, wherein a pH (25° C.) of the liquid is adjusted by diluting the liquid with a diluent mainly containing water.

8. The method for preserving an organic polymeric material as claimed in claim 7, wherein the diluent mainly contains at least one of pure water, distilled water and RO water.

9. The method for preserving an organic polymeric material as claimed in claim 1, wherein a pH (25° C.) of the liquid is adjusted by removing hydrogen ions from the liquid using a means for removing hydrogen ions.

10. The method for preserving an organic polymeric material as claimed in claim 9, wherein the removal of hydrogen ions by the hydrogen ions removing means is carried out by converting hydrogen ions into hydrogen gas.

11. The method for preserving an organic polymeric material as claimed in claim 1, wherein a temperature of the organic polymeric material during the preservation is in the range of 15 to 40° C.

12. The method for preserving an organic polymeric material as claimed in claim 1, wherein the organic polymeric material is preserved with it being shut off from the outside air.

13. The method for preserving an organic polymeric material as claimed in claim 1, wherein the organic polymeric material is preserved with it being shut off from lights.

14. The method for preserving an organic polymeric material as claimed in claim 1, wherein the organic polymeric material contains at least one of a sulfone group, a carboxyl group and a phenolic hydroxyl group.

15. The method for preserving an organic polymeric material as claimed in claim 1, wherein the organic polymeric material is a hole transport material having a function of transporting holes.

16. The method for preserving an organic polymeric material as claimed in claim 15, wherein the hole transport material is poly (3,4-ethylenedioxythiophene/styrenesulfonic acid).

17. An organic electroluminescent device having a layer mainly formed of the hole transport material which has been preserved by the method for preserving an organic polymeric material claimed in claim 15.
